(19) United States
(12) Patent Application Publication
(10) Pub. No.: US 2012/0105063 A1
(43) Pub. Date: May 3, 2012

(54) SUPERCONDUCTIVE MAGNETIC COIL COMPRISING REGIONS HAVING DIFFERING HEAT TRANSFER

(75) Inventors: Eugene Astra, Oxford (GB); Norbert Huber, Erlangen (DE); Marijn Pieter Oomen, Erlangen (DE)

(73) Assignee: SIEMENS AKTIENGESELLSCHAFT, MUNICH (DE)

(21) Appl. No.: 13/138,862

(22) PCT Filed: Mar. 18, 2010
(86) PCT No.: PCT/EP2010/053493

§ 371 Date: Jan. 3, 2012

(30) Foreign Application Priority Data
Apr. 9, 2009 (DE) 1020090170588

(51) Int. Cl. G01R 33/44; H01F 6/06

(52) U.S. Cl. 324/322; 335/216

(57) ABSTRACT

A superconductive magnetic coil is located in a cryostat for cooling purposes which is filled only up to a certain fill level with liquid helium. A helium gas phase having a temperature stratification, in which, for example, temperatures are present that can lead to a collapse of the superconductivity, forms over said helium accumulation. The magnetic coil is therefore subdivided into at least two partial regions having differing heat transfer between the coil and the surrounding medium. In a first partial region of the coil, in the surroundings of which a sufficiently low temperature for cooling is present, the heat transfer is high, while the magnetic coil in a second partial region, in the surroundings of which the temperature of the cooling medium is above a critical value, exhibits heat insulation. Consequently, no heat is exchanged between the coil and the surroundings in the second partial region, while cooling of the coil takes place in the first partial region.

### CROSS REFERENCE TO RELATED APPLICATIONS

This application is based on and hereby claims priority to International Application No. PCT/EP2010/053493 filed on Mar. 18, 2010 and German Application No. 10 2009 017 058.8 filed on Apr. 9, 2009, the contents of which are hereby incorporated by reference.

### BACKGROUND

The invention relates to a superconducting magnetic coil and to a magnetic resonance tomography system comprising a superconducting magnetic coil.

In magnetic resonance tomography (MRT), magnetic coils comprising superconducting coil windings are conventionally used in order to generate the main magnetic field, which has an order of magnitude of several tesla, for example 3T, the coil winding being placed in and/or on a winding support. For refrigeration, the magnetic coils are arranged in a cryostat, which is generally operated with liquid helium.

Conventionally, the cryostat is filled at least partially with liquid helium. This, however, is disadvantageous on the one hand for cost reasons and on the other hand because of the helium stocks which eventually run out.

In another approach to refrigeration of the superconducting magnetic coil, the liquid helium circulates in suitable pipelines. This refrigeration system, however, is elaborate and therefore likewise cost-intensive.

### SUMMARY

It is therefore one possible object to provide an economical and resource-saving way of refrigerating a superconducting magnetic coil of an MRT system.

Geometrical terms such as bottom, below, top, above etc. refer below to the vertical, i.e. the direction defined by gravitational force.

The inventors' proposals are based results from a CFD (“Computational Fluid Dynamics”, or numerical fluid dynamics) study in which the flow behavior of gaseous helium was studied with different predetermined helium filling heights or filling levels N in a cryostat which, for example, is to be used in an MRT system. In this case, it is assumed that the cryostat is only filled with liquid helium up to the filling level N, and that a helium gas phase He_{gas} is formed above the liquid helium He_{liq}. Thermal stratification additionally takes place in the helium gas phase. Higher temperatures prevail in the helium gas phase He_{gas} than in the liquid phase He_{liq}, so that for example the risk of a quench, i.e. collapse of the superconductivity, cannot be ruled out for a magnetic coil installed in the cryostat.

The study has led to the discovery that for sufficient refrigeration of a superconducting magnetic coil, which comprises a superconducting coil winding and a winding support and is arranged in the cryostat, the cryostat does not actually need to be fully filled with liquid helium. The temperature of the magnetic coil can also be kept below the critical threshold value for superconductivity with a reduced stock of liquid helium, i.e. with a low helium filling level N.

Specifically, the CFD study demonstrates that, with a low filling level N in the cryostat, regions with different temperatures are formed in the helium gas phase, i.e. above the liquid phase, in spite of convective circulations, and these have an effect on the refrigeration of the magnetic coil. In a simplified representation, FIG. 1 shows a cross section through a cryostat 20 and a magnetic coil 10 comprising a coil winding 11 and a winding support 12, as well as the regions A-D with different temperatures, which are formed in the cryostat 20. In the cross section shown here, the coil winding 11 is embedded in the winding support 12:
In a region A of the cryostat 20, there is liquid helium He_{liq}, i.e. ideal refrigeration of the coil winding takes place here. Temperatures of the coil winding and of the winding support remain in the range of the boiling point of helium (4.2-4.3 K). Because of gravity, the region A naturally lies “at the bottom” in the cryostat 20.
In a region B of the cryostat 20, which follows on immediately above the region A, the helium is gaseous (He_{gas}). The helium gas temperature T_{He} is lower than the temperature T_{coil} of the coil winding and of the winding support of the magnetic coil 10, i.e. T_{He}(B)<T_{coil}(B), so that effective refrigeration still takes place here as well.
There is also gaseous helium He_{gas} in a region C of the cryostat 20, which lies directly above B. The helium gas temperature T_{He} and the temperature T_{coil} of the coil winding and of the winding support are equal, i.e. T_{He}(C)=T_{coil}(C).
There is also gaseous helium He_{gas} in a region D of the cryostat 20 immediately above C. The gas temperature T_{He} is higher than the temperature T_{coil} of the coil winding and of the winding support, i.e. T_{He}(D)>T_{coil}(D), since heat enters in particular through a wall 21 of the cryostat 20. The effect of this is that the coil winding in the region D is heated directly by the helium gas and indirectly through the winding support, so that a quench is more likely to occur in this region.

The extent of the regions A-D in the vertical direction depends on the filling level N of the liquid helium He_{liq} in the cryostat, and on heat possibly entering from outside the cryostat.

On the basis of these discoveries, it is proposed to adapt the heat transfer between the magnetic coil and the surrounding refrigerant to the conditions respectively prevailing locally in the various regions A-D: subregions of the magnetic coil which lie in regions where refrigeration of the magnetic coil takes place, since the temperature of the surrounding refrigerant is lower than the temperature of the magnetic coil, are configured so that large heat transfer is possible between the magnetic coil and the refrigerant. Here, it is thus possible to exchange a large quantity of heat between the magnetic coil and the surrounding medium, so that a large quantity of heat can be dissipated from the magnetic coil to the helium. In the nomenclature above, this relates to the regions A and B of the cryostat.

In addition or as an alternative, subregions of the magnetic coil, which lie in regions where the temperature of the surrounding medium is higher than the temperature of the magnetic coil, are configured so as to hinder the transfer of a quantity of heat between the magnetic coil and the surrounding medium, so that ideally no heat can be transferred from the refrigerant to the magnetic coil. Consequently, in this region, the magnetic coil is not heated, or is heated only minimally, by the surrounding medium. In the nomenclature above, this relates in particular to the region D.

The inventors accordingly propose a superconducting magnetic coil having at least a first subregion and a second subregion, the subregions being spatially separated from one another and being in thermal contact with a refrigerant. The heat transfer between the first subregion and the refrigerant is greater than the heat transfer between the second subregion and the refrigerant.

Advantageously, this is achieved by the heat transfer coefficients in the subregions of the magnetic coil being dimensioned differently. The heat transfer coefficient in the first subregion is greater than the heat transfer coefficient in the second subregion. The effect achieved by the properties of the magnetic coil and the surrounding refrigerant being adapted to one another in this way is that a greater quantity of heat can be exchanged in the first subregion than in the second subregion.

In an advantageous configuration, the subregions of the magnetic coil have different thermal conduction coefficients, the thermal conduction coefficient of the first subregion being greater than the thermal conduction coefficient of the second subregion. The properties of the magnetic coil, optimized in this way, allow the first subregion of the magnetic coil to be suitable for releasing a large quantity of heat to the refrigerant, while the second subregion is formed so as to receive only a comparatively small quantity of heat from the surrounding refrigerant.

Advantageously, in the first subregion, the magnetic coil comprises surface structures, in particular grooves, ribs and/or textures, for increasing the surface area of the magnetic coil. Increased heat transfer is thereby achieved at the interface between the first subregion and the refrigerant.

Advantageously, in the second subregion, the magnetic coil comprises thermal insulation which thermally insulates the magnetic coil from the refrigerant. The heat transfer between the second subregion and the refrigerant is thereby reduced.

Advantageously, in the second subregion, for thermal insulation, the magnetic coil is provided with a coating, in particular a synthetic resin coating, or is wound with a thermally insulating material. The heat transfer between the second subregion and the refrigerant is thereby reduced.

In a particular configuration, the magnetic coil comprises a winding support in addition to the actual current-carrying coil winding. The heat transfer coefficient of the winding support in the first subregion of the magnetic coil is greater than the heat transfer coefficient of the winding support in the second subregion of the magnetic coil.

In another configuration, the thermal conduction coefficient of the winding support in the first subregion of the magnetic coil is greater than the thermal conduction coefficient of the winding support in the second subregion of the magnetic coil.

Advantageously, the magnetic coil comprises insulation, in particular electrical insulation, the insulation in the first subregion of the magnetic coil having a higher thermal conduction coefficient than the insulation in the second subregion of the magnetic coil.

A magnetic resonance tomography system proposed by the inventors comprises the proposed superconducting magnetic coil and a cryostat, which contains a refrigerant. The magnetic coil is arranged in the cryostat.

Advantageously, the refrigerant is present in at least two aggregate states in the cryostat, particularly a gaseous state and a liquid state.

In an advantageous configuration, the magnetic coil is arranged in the cryostat so that the first subregion of the magnetic coil is surrounded at least partially by liquid refrigerant and the second subregion of the magnetic coil is surrounded at least partially by gaseous refrigerant.

### BRIEF DESCRIPTION OF THE DRAWINGS

These and other objects and advantages of the present invention will become more apparent and more readily appreciated from the following description of the preferred embodiments, taken in conjunction with the accompanying drawings of which:

FIG. 1 shows a cross section through a cryostat and a magnetic coil contained therein, with a representation of the temperature regions which are formed,

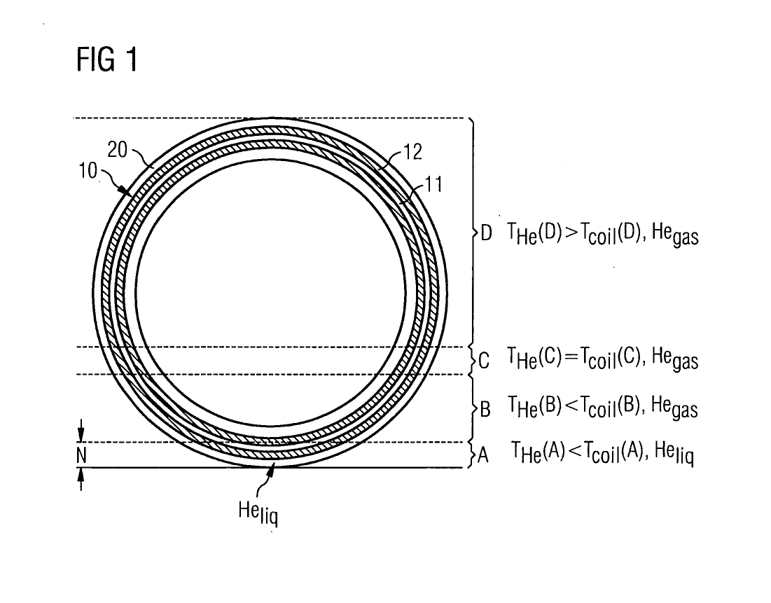

FIG. 2 shows a 3D view of a cryostat and a magnetic coil,

FIG. 3 shows a cross section through a cryostat and a magnetic coil contained therein, with a representation of the temperature regions which are formed and two subregions of the magnetic coil,

FIG. 4 shows a cross section through a cryostat and a magnetic coil contained therein, with a representation of the temperature regions which are formed and three subregions of the magnetic coil at two different times.

### DETAILED DESCRIPTION OF THE PREFERRED EMBODIMENT

Reference will now be made in detail to the preferred embodiments of the present invention, examples of which are illustrated in the accompanying drawings, wherein like reference numerals refer to like elements throughout.

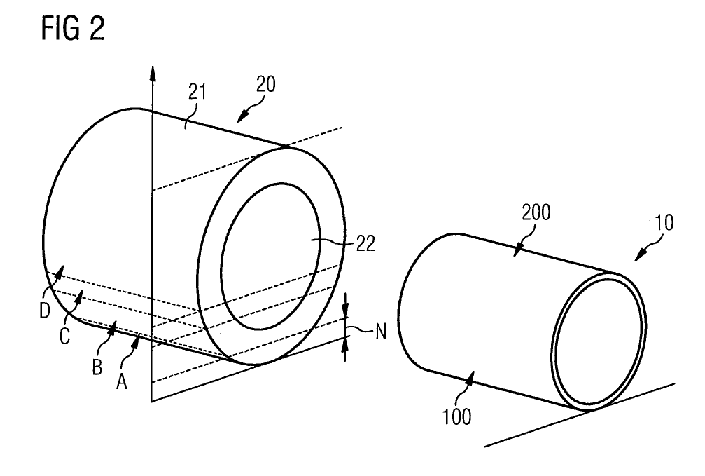

FIG. 2 shows by way of example a simplified illustrative representation of a superconducting magnetic coil 10 to be refrigerated, and a cryostat 20. The magnetic coil 10 and the cryostat 20 are represented separately from one another in FIG. 2. In the assembled state, for example for an MRT system, the magnetic coil 10 is fitted into the cryostat 20. Only one magnetic coil 10 is represented in the figures for simplicity, although in reality it generally comprises a system having a plurality of individual magnetic coils.

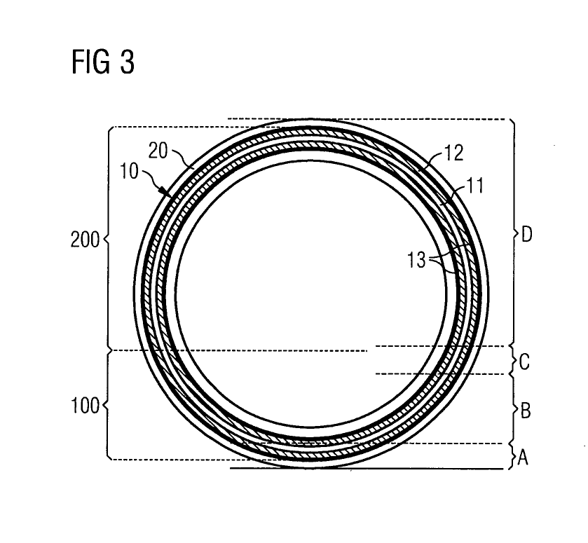

The magnetic coil 10 has the shape of a thick-walled hollow cylinder with a circular cylindrical cross section and generally includes (although not shown in detail here) a winding support and a superconducting coil winding, which in turn is formed from a multiplicity of turns of a superconducting conductor. The coil winding may be partially embedded in the winding support and partially applied externally or internally onto the winding support. The magnetic coil 10 may furthermore be surrounded by electrical insulation 13 (represented in FIG. 3), in order to prevent possible short circuits and voltage sparkover to neighboring coils and to grounded components. The electrical insulation 13 may, be formed from various plastics and casting resins, for example an epoxy resin (for example “Stycast”) with an aluminum oxide powder or with glass beads.

The cryostat 20 principle is formed from two coaxially arranged hollow cylinders 21, 22 of different diameters placed in one another. The space between the lateral surfaces of the cylinders 21, 22 is closed on the end sides of the cylinders, so that the space can hold a refrigerant, for example helium. Typically, the diameter of the outer cylinder 21 is about 2 m while the diameter of the inner cylinder 22 is about 1 m. The length of the cylinders is about 2 m. In order to scan a patient using the MRT system, he or she is supported inside the inner cylinder 22 on a patient table (not shown).

In order to ensure superconductivity of the magnetic coil 10, or the coil winding, it needs to be refrigerated to an appropriate temperature. To this end, the magnetic coil 10 is placed in the cryostat 20 in the aforementioned space between the lateral surfaces of the cylinders 21, 22. As already mentioned, the refrigerant (helium) required for refrigerating the magnetic coil 10 and in particular the superconducting coil winding is also contained therein. The magnetic coil 10 is in thermal contact with the helium, so that heat transfer between the magnetic coil 10 and the helium is ensured. The space is not however filled fully with liquid helium He_{liq}, but instead only partially, and this accumulates at the bottom in the cryostat in a helium pool because of gravity.

Depending on the quantity introduced, the surface of the helium pool lies at a filling level N. Below the filling level N, the region referred to in the introduction as “region A” is formed in which there is liquid helium He_{liq}. Immediately above the level N, the liquid phase He_{liq} is followed by the helium gas phase He_{gas}; the region B is formed in which the gas temperature T_{He} is lower than the magnetic coil temperature T_{coil}. In turn immediately above the region B, i.e. in the region C, the gas temperature T_{He} is equal to the temperature of the magnetic coil T_{coil}, while in the region D lying above the gas temperature T_{He} is higher than the magnetic coil temperature T_{coil}. The effects resulting therefrom on the refrigeration of the magnetic coil 10 have been summarized in the introduction: a subregion 100 (cf. FIGS. 2 and 3) of the magnetic coil 10, which advantageously, when the magnetic coil 10 is installed in the cryostat 20, lies in the region A and optionally also at least partially in the region B of the cryostat 20, can be refrigerated, while for a subregion 200 of the magnetic coil 10 which lies in the region D, there is the disadvantage that it is heated.

According to the inventors' proposal, the magnetic coil 10 is formed so that it comprises at least two subregions 100, 200 which have different thermal conduction coefficients or heat transfer coefficients. Correspondingly, the coil winding 11 and/or the winding support 12 are also subdivided into the two subregions.

The thermal conduction coefficient is a material parameter and is indicated with the unit W/m/K. The heat transfer coefficient, in contrast to the thermal conduction coefficient, is a number which characterizes the heat flux between two bodies or between a body and a fluid. Its unit is W/m²/K. In other words, the heat transfer coefficient represents a measure of the quantity of heat, or the thermal energy, exchanged between two media at an interface, i.e. a measure of the heat transfer from one medium to another when there is a temperature difference. In this context, a large heat transfer coefficient means that a large quantity of heat can be transported from one medium to the other even when there is a small temperature difference. This is equivalent to saying that an object such as the magnetic coil can be efficiently refrigerated by a refrigerant on condition that the refrigerant is colder than the object, when there is a large heat transfer coefficient.

The heat transfer coefficient is on the one hand material-dependent. For example, thermally insulating materials have a low heat transfer coefficient. Specifically, the heat transfer coefficient depends on the temperature difference between the media and on the specific heat capacity, the density and the thermal conduction coefficients of the medium discharging heat and the medium delivering heat. Furthermore, the heat transfer naturally depends on the size of the interface, or the surface area between the media.

In the first subregion 100 of the magnetic coil 10 which, when the magnetic coil 10 is installed in the cryostat 20, lies for example in the regions A, B of the cryostat 20, there is a large heat transfer coefficient. The large heat transfer coefficient ensures strong heat transfer between the refrigerant 30 and the magnetic coil 10, so that a large quantity of heat can be dissipated from the magnetic coil 10 to the refrigerant 30 or, with a given quantity of heat to be dissipated, the coil temperature is only slightly higher than the temperature of the refrigerant.

The second subregion 200 of the magnetic coil 10, in the installed state of the magnetic coil 10 in the cryostat 20, lies in the region D. There is a low heat transfer coefficient in the subregion 200, so that only minimal exchange of heat is possible between the magnetic coil 10 and the refrigerant 30. The effect of the low heat transfer coefficient is that the temperature of the magnetic coil 10 remains substantially constant in the subregion 200, since the heat transfer between the magnetic coil 10 and the refrigerant 30 is minimal at this position. The heat entering the coil in region D must be dissipated again in regions A and B. A low heat transfer coefficient in region D thus in turn assists in ensuring that the coil does not become much warmer than the refrigerant in regions A and B.

By a suitable material selection for the magnetic coil 10, in particular for the winding support 12, the heat transfer coefficient can therefore be influenced according to requirements. Furthermore, the heat transfer coefficient can be increased by enlarging the interface between the media, i.e. between the magnetic coil 10 and the refrigerant 30.

In order to ensure the increased heat transfer in the subregion 100, the interface between the magnetic coil 10 and the surrounding refrigerant 30 may be enlarged, for example in comparison with a smooth-surfaced magnetic coil. To this end, surface structures 110 are introduced into the surface of the magnetic coil 10, for example grooves, ribs or other textures. In addition or as an alternative, a material with high thermal conduction or with a large thermal conduction coefficient is selected for the electrical insulation 13 of the magnetic coil 10, for example insulation materials with thermal conductivities which greatly exceed a value of 0.2 W/m/K. Furthermore, the winding support 12 may also be made of a material with high thermal conductivity in the subregion 100. Typically, the winding support 12 is formed of an aluminum alloy. Nevertheless, for example, glass fiber-reinforced plastics (GFP) are also suitable.

In order to minimize the heat transfer in the subregion 200, the subregion 200 is in the simplest case equipped with thermal insulation 210 having a low heat transfer coefficient and a low thermal conduction coefficient. For example, the subregion 200 of the magnetic coil 10 may be dipped in a synthetic resin bath before it is installed in the cryostat 20, so that the subregion 200 is coated with an additional insulating synthetic resin coating 210. As an alternative, this insulating coating 210 may for example be sprayed or brushed on. It is furthermore conceivable to package or wind the subregion 200 with an insulating material 210, for example Teflon or Kapton tapes or films. Synthetic resin-impregnated windings are also suitable.

It is likewise conceivable to make the winding support 12 in the subregion 200 from a material with a low thermal conduction coefficient, while the winding support in the subregion 100 is formed of a material with a high thermal conduction coefficient.

Particularly for open systems, in which the filling level N decreases over time, when configuring and dimensioning the subregions 100 and 200 of the magnetic coil 10 it is necessary to bear in mind that the filling level N of the liquid helium 30 decreases over time during normal operation after initial introduction into the cryostat 20. With the filling level N, the regions B and C are also lowered down relative to the magnetic coil 10, while the region D extends downward. This can have the effect that a region which initially was assigned e.g. to the region B is to be assigned to the region C after a certain time. Accordingly, the magnetic coil is initially also refrigerated there (in the region B, T_{He}<T_{coil}) but later, when the region C has correspondingly been lowered further, it is no longer refrigerated. In the extreme case, the filling level N and the regions B, C are lowered so much that the region D extends into regions where refrigeration of the magnetic coil 10 initially took place as well.

In another embodiment, the magnetic coil 10 may comprise a further subregion 300 which is arranged between the subregions 100 and 200. The heat transfer coefficient in the subregion 300 has a value which lies between the heat transfer coefficients of the subregions 100 and 200.

Ideally, the subregions 100, 200, 300 are dimensioned as a function of the initial filling level N of the liquid helium in the cryostat 20. In this case, it is assumed that the filling level to which the cryostat 20 is conventionally filled is known a priori. Since, for normal operation of the cryostat, the way in which the filling level N and the position and extent of the regions A, B, C, D change over time is known, as well as the minimum filling level N at which liquid helium is topped up again, the dimensioning of the subregions 100, 200, 300 of the magnetic coil 10 can be optimized with respect to this change.

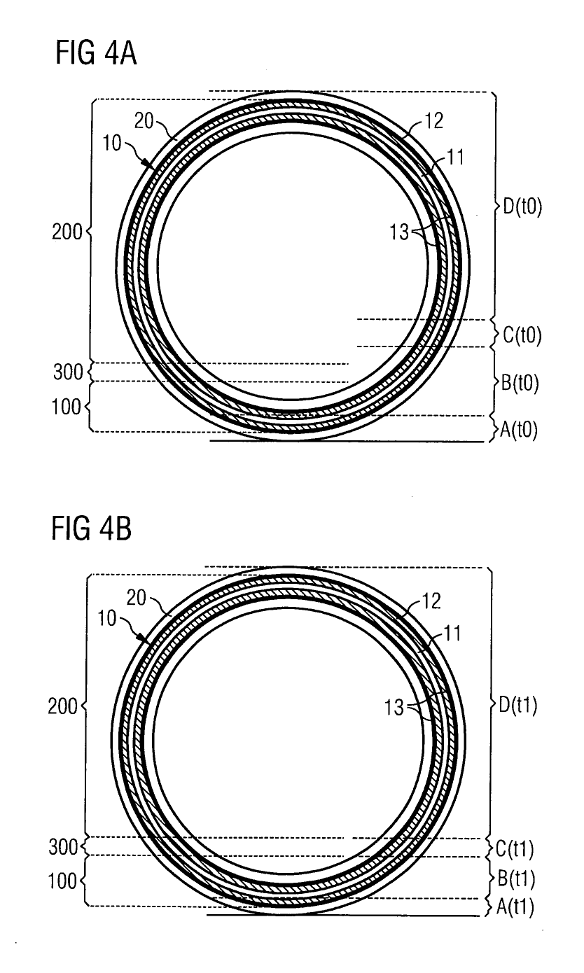

For example, the dimensioning may be carried out as indicated in FIG. 4. FIG. 4A shows the position and extent of the regions A, B, C, D at a time t0 immediately after the cryostat is filled up to the filling level N. FIG. 4B shows the regions A, B, C, D at a later time t1, at which the cryostat 20 is conventionally refilled with liquid helium. The subregions 100, 200, 300 of the magnetic coil 10 may, for example, be dimensioned so that the subregion 300 is substantially covered by the region C at the time t1. This ensures that the comparatively warm region D does not advance into the subregion 100 of the magnetic coil 10, in which large heat transfer is possible between the magnetic coil 10 and the refrigerant 30. The proposed dimensioning naturally represents merely one of many possibilities. Other models for dimensioning the subregions 100, 200, 300 may likewise be envisaged, although it is fundamentally necessary to bear in mind that the position and extent of the regions A, B, C, D changes over time.

Even more extensive adaptation is possible by equipping the magnetic coil 10 with four or more subregions.

The invention has been described in detail with particular reference to preferred embodiments thereof and examples, but it will be understood that variations and modifications can be effected within the spirit and scope of the invention covered by the claims which may include the phrase “at least one of A, B and C” as an alternative expression that means one or more of A, B and C may be used, contrary to the holding in Superguide v. DIRECTV, 69 USPQ2d 1865 (Fed. Cir. 2004).

1-12. (canceled)

13. A superconducting magnetic coil comprising:
a first subregion of the magnetic coil, in thermal contact with a refrigerant such that there is greater heat transfer between the first subregion and the refrigerant; and
a second subregion of the magnetic coil, the second subregion being spatially separated from the first subregion and being in thermal contact with the refrigerant such that there is lesser heat transfer between the second subregion and the refrigerant.

14. The superconducting magnetic coil as claimed in claim 13, wherein
the first and second subregions of the magnetic coil have different heat transfer coefficients, and
the heat transfer coefficient in the first subregion is greater than the heat transfer coefficient in the second subregion.

15. The superconducting magnetic coil as claimed in claim 13, wherein
the first and second subregions of the magnetic coil have different thermal conduction coefficients, and
the thermal conduction coefficient of the first subregion is greater than the thermal conduction coefficient of the second subregion.

16. The superconducting magnetic coil as claimed in claim 13, wherein
in the first subregion, the magnetic coil comprises surface structures for increasing surface area of the magnetic coil, and
the surface structures are selected from the group consisting of grooves, ribs and textures.

17. The superconducting magnetic coil as claimed in claim 13, wherein in the second subregion, the magnetic coil comprises thermal insulation which thermally insulates the magnetic coil from the refrigerant.

18. The superconducting magnetic coil as claimed in claim 17, wherein the thermal insulation in the second subregion is selected from the group consisting of a synthetic resin coating and a thermally insulating winding.

19. The superconducting magnetic coil as claimed in claim 13, wherein
the magnetic coil comprises a winding support,
in the first subregion of the magnetic coil, the winding support has a greater heat transfer coefficient, and
in the second subregion of the magnetic coil, the winding support has a lesser heat transfer coefficient.

20. The superconducting magnetic coil as claimed in claim 13, wherein
the magnetic coil comprises a winding support,
in the first subregion of the magnetic coil, the winding support has a greater thermal conduction coefficient, and
in the second subregion of the magnetic coil, the winding support has a lesser thermal conduction coefficient.

21. The superconducting magnetic coil as claimed in claim 13, wherein
the magnetic coil comprises electrical insulation,
in the first subregion of the magnetic coil, the electrical insulation has a greater thermal conduction coefficient,
in the second subregion of the magnetic coil, the electrical insulation has a lesser thermal conduction coefficient.

22. A magnetic resonance tomography (MRT) system comprising:
a cryostat which contains a refrigerant; and
a superconducting magnetic coil provided in the cryostat, the superconducting magnetic coil comprising:
a first subregion of the magnetic coil, in thermal contact with a refrigerant such that there is greater heat transfer between the first subregion and the refrigerant; and
a second subregion of the magnetic coil, the second subregion being spatially separated from the first subregion and being in thermal contact with the refrigerant such that there is lesser heat transfer between the second subregion and the refrigerant.

23. The magnetic resonance tomography (MRT) system as claimed in claim 22, wherein
the refrigerant is present in a liquid state in first portion of the cryostat, and
the refrigerant is present in a gaseous state in a second portion of the cryostat.

24. The magnetic resonance tomography (MRT) system as claimed in claim 23, wherein the magnetic coil is arranged in the cryostat so that the first subregion of the magnetic coil is surrounded at least partially by liquid refrigerant and the second subregion of the magnetic coil is surrounded at least partially by gaseous refrigerant.

25. The magnetic resonance tomography (MRT) system as claimed in claim 20, wherein
the first and second subregions of the magnetic coil have different heat transfer coefficients, and
the heat transfer coefficient in the first subregion is greater than the heat transfer coefficient in the second subregion.

26. The magnetic resonance tomography (MRT) system as claimed in claim 22, wherein
the first and second subregions of the magnetic coil have different thermal conduction coefficients, and
the thermal conduction coefficient of the first subregion is greater than the thermal conduction coefficient of the second subregion.

27. The magnetic resonance tomography (MRT) system as claimed in claim 22, wherein
in the first subregion, the magnetic coil comprises surface structures for increasing surface area of the magnetic coil, and
the surface structures are selected from the group consisting of grooves, ribs and textures.

28. The magnetic resonance tomography (MRT) system as claimed in claim 22, wherein in the second subregion, the magnetic coil comprises thermal insulation which thermally insulates the magnetic coil from the refrigerant.

29. The magnetic resonance tomography (MRT) system as claimed in claim 28, wherein the thermal insulation in the second subregion is selected from the group consisting of a synthetic resin coating and a thermally insulating winding.

30. The magnetic resonance tomography (MRT) system as claimed in claim 22, wherein
the magnetic coil comprises a winding support,
in the first subregion of the magnetic coil, the winding support has a greater heat transfer coefficient, and
in the second subregion of the magnetic coil, the winding support has a lesser heat transfer coefficient.

31. The magnetic resonance tomography (MRT) system as claimed in claim 22, wherein
the magnetic coil comprises a winding support,
in the first subregion of the magnetic coil, the winding support has a greater thermal conduction coefficient, and
in the second subregion of the magnetic coil, the winding support has a lesser thermal conduction coefficient.

32. The magnetic resonance tomography (MRT) system as claimed in claim 22, wherein
the magnetic coil comprises electrical insulation,
in the first subregion of the magnetic coil, the electrical insulation has a greater thermal conduction coefficient,
in the second subregion of the magnetic coil, the electrical insulation has a lesser thermal conduction coefficient.
